(19) United States
(12) Patent Application Publication
(10) Pub. No.: US 2016/0293872 A1
(43) Pub. Date: Oct. 6, 2016

(54) INORGANIC NANOMATERIAL-BASED HYDROPHOBIC CHARGE CARRIERS, METHOD FOR PREPARING THE CHARGE CARRIERS AND ORGANIC-INORGANIC HYBRID PEROVSKITE SOLAR CELL INCLUDING THE CHARGE CARRIERS

(71) Applicant: KOREA INSTITUTE OF SCIENCE AND TECHNOLOGY, Seoul (KR)

(72) Inventors: Min Jae KO, Seoul (KR); Hae Jung SON, Seoul (KR); Jin Young KIM, Seoul (KR); Doh-Kwon LEE, Seoul (KR); Hee Suk JUNG, Seoul (KR); Bonkee KOO, Seoul (KR)

(21) Appl. No.: 15/084,309

(22) Filed: Mar. 29, 2016

(30) Foreign Application Priority Data
Apr. 3, 2015 (KR) 10-2015-0047651

(51) Int. Cl. H01L 51/42

(52) U.S. Cl. CPC H01L 51/4213; H01L 51/0083

(57) ABSTRACT

Disclosed are inorganic nanomaterial-based hydrophobic charge carriers and an organic-inorganic hybrid perovskite solar cell using the charge carriers. In the solar cell, the charge carriers are used as materials for a charge transport layer. The solar cell has high photoelectric efficiency for its price. In addition, the solar cell is prevented from being degraded by moisture. Therefore, the solar cell can be operated stably for a long time despite long-term exposure to a humid environment.

### CROSS-REFERENCE TO RELATED APPLICATIONS

This application claims priority under 35 U.S.C. §119 to Korean Patent Application No. 10-2015-0047651 filed on Apr. 3, 2015 in the Korean Intellectual Property Office, the disclosure of which is incorporated herein by reference in its entirety.

### BACKGROUND OF THE INVENTION

1. Field of the Invention

The present invention relates to inorganic nanomaterial-based hydrophobic charge carriers and an organic-inorganic hybrid perovskite solar cell using the charge carriers. More specifically, the present invention relates to hydrophobic charge carriers based on a nanomaterial and an organic-inorganic hybrid perovskite solar cell in which the charge carriers are used as materials for a charge transport layer.

2. Description of the Related Art

With the recent increasing use of fossil fuels worldwide, environmental pollution problems have become increasingly serious. Thus, there arises a need to develop renewable energy sources using clean energy. Many renewable energy sources based on sunlight have been developed to date. Among them, solar cells are devices that directly convert solar energy into electrical energy. Since solar cells utilize the inexhaustible and environmentally friendly energy resource, they are expected as promising energy sources that can be used semi-permanently.

Dye-sensitized solar cells are considered as next generation solar cells. Dye-sensitized solar cells mimic the photosynthetic process in plants and use an artificially synthesized dye rather than a natural dye. The artificially synthesized dye is adsorbed to titanium dioxide (TiO₂) nanoparticles and generates electrons from incident sunlight. The electrons flow through an external circuit to produce electrical energy. After the electrical event, the electrons return to the dye via an electrolyte or a hole transport layer. This cycle enables repeated operation of the solar cells.

Starting from such dye-sensitized solar cells, research has been conducted on solar cells based on organic-inorganic hybrid perovskite light absorbers that have high potential for commercialization due to their high efficiency and simple fabrication process. Due to these advantages, dye-sensitized solar cells have received considerable attention as next generation solar cell technology that has the potential to replace existing silicon solar cells. 2,22′,7,77′-tetrkis(N,N-di-p-methoxyphenylamine)-9,99′-spirobifluorine (Spiro-OMeTAD), a representative hole carrier that is currently used in perovskite-based solar cells, is disadvantageous in that its price is relatively high compared to gold and platinum.

Further, perovskite light absorbers susceptible to moisture are liable to degrade. To prevent this degradation, charge transport layers formed on absorber layers are required to have a good ability to block moisture. Under these circumstances, more research needs to be conducted to develop charge carriers based on inexpensive hydrophobic nanoparticles with an outstanding ability to block moisture for the commercialization of perovskite-based solar cells.

### PRIOR ART DOCUMENTS

### Patent Documents

Korean Patent No. 10-1461641

### Non-Patent Documents

1. Nature Comm. 5, 3834, 2014, Peng Qin et al.
2. J. Am. Chem. Soc., 136, 758-764, 2013, 5, 5201-5207, Jeffrey A. Christians et al.

### SUMMARY OF THE INVENTION

It is an object of the present invention to economically fabricate a solar cell in which hydrophobic charge carriers based on an environmentally friendly and inexpensive inorganic nanomaterial are introduced instead of conventional solid charge carriers based on expensive organic materials, ensuring excellent photoelectric properties and long-term stability. The present inventors have found that when inexpensive nanostructures imparted with hydrophobicity are used as charge carriers, an organic-inorganic hybrid perovskite light absorber susceptible to moisture in air can be prevented from degradation, enabling the fabrication of an organic-inorganic hybrid perovskite solar cell with high efficiency and stability that is suitable for commercialization. The present invention has been accomplished based on this finding.

One aspect of the present invention is directed to a charge transport layer for a solar cell including core-shell nanoparticles consisting of (a) an inorganic nanoparticle core and (b) an organic material shell surrounding the surface of the inorganic nanoparticle core.

The term “core-shell nanoparticles” used herein refers to inorganic nanoparticles coated with an organic material. More specifically, the core-shell nanoparticles refer to inorganic nanoparticles coated with a ligand having a long hydrophobic chain.

A further aspect of the present invention is directed to a solar cell including the charge transport layer.

Another aspect of the present invention is directed to a method for forming a charge transport layer for a solar cell, including (A) heating a mixture solution of (i) a first precursor solution including a first inorganic nanoparticle precursor and an organic material and (ii) a second precursor solution including a second inorganic nanoparticle precursor and a solvent.

The solar cell of the present invention has high photoelectric efficiency for its price. In addition, the solar cell of the present invention is prevented from being degraded by moisture. Therefore, the solar cell of the present invention can be operated stably for a long time despite long-term exposure to a humid environment.

The charge transport layer of the present invention uses an inorganic material, which is less expensive than organic materials used in charge transport layers of conventional organic-inorganic hybrid solar cells, advantageously achieving high energy conversion efficiency of the organic-inorganic hybrid perovskite solar cell according to the present invention for its price. In addition, the charge transport layer of the present invention is imparted with hydrophobicity. Due to this hydrophobicity, the organic-inorganic hybrid solar cell is prevented from being degraded by moisture, which is a problem encountered in existing organic-inorganic hybrid solar cells, and has high long-term stability. Furthermore, the organic-inorganic hybrid solar cell of the present invention uses nanoparticles or composites including nanoparticles as charge carriers, which can make the device flexible or stretchable.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1a is a cross-sectional view of a normal-type solar cell in which a hydrophobic hole transport layer and an electron transport layer are present at the upper and lower ends of a perovskite light absorber, respectively;

FIG. 1b is a cross-sectional view of an inverted-type solar cell in which a hydrophobic electron transport layer and a hole transport layer are present at the upper and lower ends of a perovskite light absorber, respectively;

FIG. 2 schematically shows a reaction for the synthesis of iron pyrite-based hydrophobic nanoparticles and a diagram of a solar cell in which the nanoparticles are used as materials for a hole transport layer;

FIG. 3a is a curve showing photocurrent-voltage characteristics of a solar cell fabricated in Example 1, which were measured under 1 sun, AM 1.5 G illumination;

FIG. 3b shows curves comparing photocurrent-voltage characteristics of a perovskite solar cell fabricated in Example 1, which were measured under 1 sun, AM 1.5 G illumination after 1 day and 45 days of storage in air, revealing that the solar cell maintained 96% of its initial photoelectric properties even after 45 days;

FIG. 4a is a curve showing a change in the photocurrent of a solar cell relative to its initial photocurrent as a function of storage time in air, revealing that the solar cell maintained 96% of the initial photocurrent; and

FIG. 4b is a graph showing a change in the photoelectric efficiency of a solar cell relative to its initial photoelectric efficiency as a function of storage time in air, revealing that that the solar cell maintained 96% of the initial conversion efficiency.

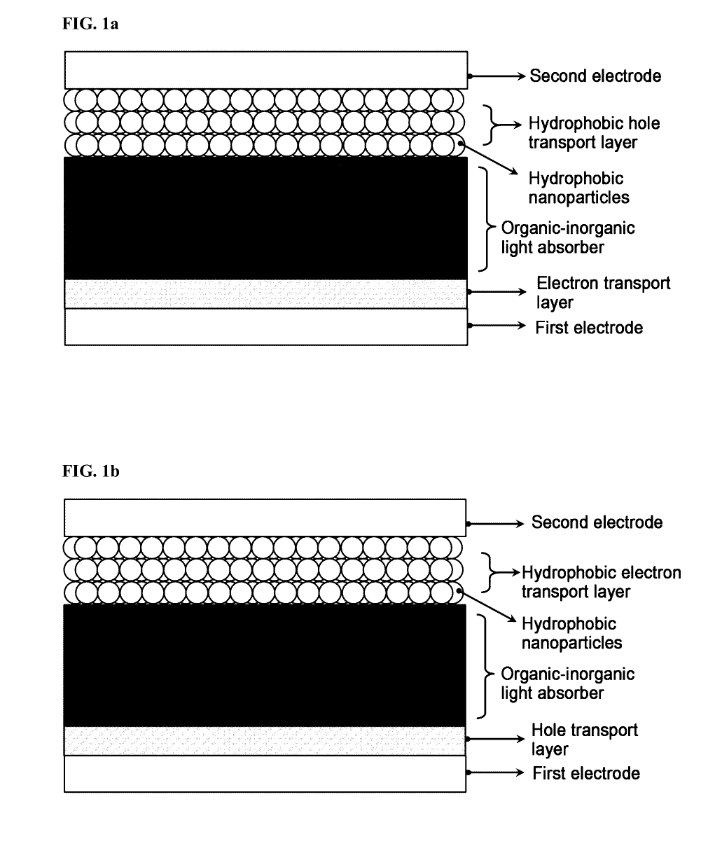

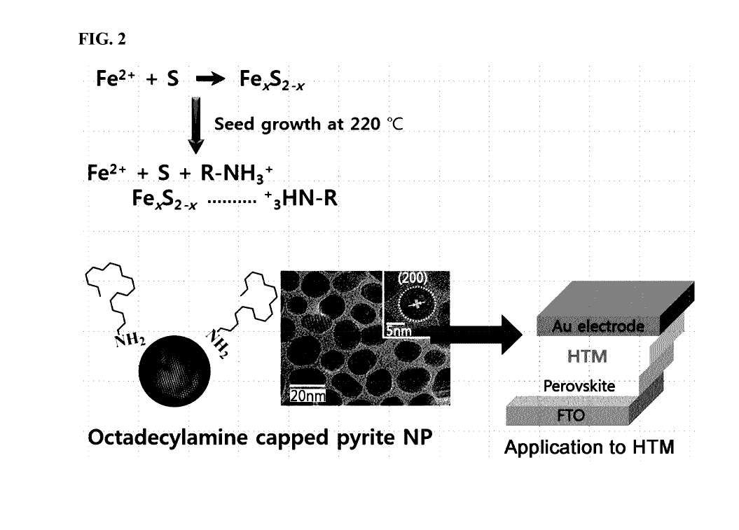

### DETAILED DESCRIPTION OF THE INVENTION

Several aspects and various embodiments of the present invention will now be described in more detail.

One aspect of the present invention is directed to a charge transport layer for a solar cell including core-shell nanoparticles consisting of (a) an inorganic nanoparticle core and (b) an organic material shell surrounding the surface of the inorganic nanoparticle core.

According to one embodiment, the inorganic nanoparticles are nanoparticles of a material selected from FeₓS_{y} (x is an integer from 1 to 7 and y is an integer from 1 to 8), FeₐO_{b} (a is an integer from 1 to 4 and b is an integer from 1 to 4), CuI, CuF, CuCl, CuBr, Cu₂O, CuSCN, and mixtures thereof.

For example, the inorganic nanoparticles may be FeS, Fe₃S₄, Fe₁₋ₓS (x is from 0.0001 to 0.2), Fe₇S₈, (x is from 0.0001 to 0.1), FeS₂, and Fe₂S₃ nanoparticles. Specific examples of the inorganic nanoparticles include FeO, Fe₂O₃, Fe₃O₄, Fe₄O₃, Fe₄O₃ or Fe₄O₅ nanoparticles.

According to a further embodiment, the organic material is selected from octadecylamine, oleylamine, dibenzylamine, oleic acid, polyvinylpyrrolidone, poly(allylamine hydrochloride), polyethyleneimine, poly(maleic anhydride-alt-1-octadecene)-polyethylene glycol block copolymers, amphiphilic polyethylene glycol-phospholipid, polystyrene-polyacrylic acid block copolymers, tetradecyl phosphonate, polyethylene glycol-2-tetradecyl ether, and mixtures thereof.

According to another embodiment, the inorganic nanoparticles are FeS₂ nanoparticles and the organic material is octadecylamine. Particularly, when FeS₂ nanoparticles and octadecylamine are used as the inorganic nanoparticles and the organic material, respectively, the long alkyl chain of the octadecylamine renders the nanoparticles hydrophobic. Due to this hydrophobicity, the charge transport layer of the present invention can advantageously block the ingress of moisture when applied to a perovskite solar cell. In addition, the charge transport layer of the present invention can completely block the occurrence of ion exchange in a solar cell, which could not be achieved by any combination of inorganic nanoparticles and an organic material other than those used in the charge transport layer of the present invention.

According to another embodiment, the charge transport layer is a hole transport layer.

A further aspect of the present invention is directed to a solar cell including the charge transport layer.

According to one embodiment, the solar cell further includes an organic-inorganic hybrid perovskite absorber layer.

According to a further embodiment, the organic-inorganic hybrid perovskite absorber layer is composed of two or more organometal halides.

For example, the organic-inorganic hybrid perovskite absorber layer may be composed of three organometal halides represented by Formulae 1, 2, and 3:

ABX₃ (1)

wherein A is CH₃NH₃⁺, NH₂CHNH₂⁺ or Cs⁺, B is a divalent metal ion, such as cu²⁺, Ni²⁺, Co²⁺, Fe²⁺, Mn²⁺, Cr²⁺, Pd²⁺, Cd²⁺, Ge²⁺, Sn²⁺, Pb²⁺, Eu²⁺ or Yb²⁺, and X is Br⁻, Sn⁻ or Cl⁻,

A′B′(X₁₍₁₋ₘ₎X₂₍ₘ₎)₃ (2)

wherein A′ is CH₃NH₃⁺, NH₂CHNH₂⁺ or Cs⁺, B′ is a divalent metal ion, such as cu²⁺, Ni²⁺, Co²⁺, Fe²⁺, Mn²⁺, Cr²⁺, Pd²⁺, Cd²⁺, Ge²⁺, Sn²⁺, Pb²⁺, Eu²⁺ or Yb²⁺, X₁ Br⁻, I⁻, Sn⁻ or Cl⁻, X₂ is Br⁻, I⁻, Sn⁻ or Cl⁻, and m is a real number from 0.0001 to 1, and

A″B″(X₁₍₁₋ₘ₎X₂₍ₘ₎)_{3-y}X_{3y} (3)

wherein A″ is CH₃NH₃⁺, NH₂CHNH₂⁺ or Cs⁺, B″ is a divalent metal ion, such cu²⁺, Ni²⁺, Co²⁺, Fe²⁺, Mn²⁺, Cr²⁺, Pd²⁺, Cd²⁺, Ge²⁺, Sn²⁺, Pb²⁺, Eu²⁺ or Yb²⁺, X₁ is Br⁻, I⁻, Sn⁻ or Cl⁻, X₂ is Br⁻, Sn⁻ or Cl⁻, X₃ is Br⁻, Sn⁻ or Cl⁻, m is a real number from 0.0001 to 1, and y is a real number from 0.0001 to 1.

According to another embodiment, the solar cell includes (a) a transparent conductive substrate, (b) a metal oxide thin film formed on the transparent conductive substrate, (c) the absorber layer formed on the metal oxide thin film, (d) the charge transport layer formed on the absorber layer, and (e) an electrode formed on the charge transport layer. In the structure of the solar cell, the organic-inorganic hybrid charge transport layer imparted with hydrophobicity serves as a hole transport layer.

According to an alternative embodiment, the solar cell includes (a) a transparent conductive substrate, (b) a hole transport layer formed on the transparent conductive substrate, (c) the absorber layer formed on the hole transport layer, (d) the charge transport layer formed on the absorber layer, and (e) an electrode formed on the charge transport layer. In the structure of the solar cell, the organic-inorganic hybrid charge transport layer imparted with hydrophobicity serves as an electron transport layer.

Another aspect of the present invention is directed to a method for forming a charge transport layer for a solar cell, including (A) heating a mixture solution of (i) a first precursor solution including a first inorganic nanoparticle precursor and an organic material and (ii) a second precursor solution including a second inorganic nanoparticle precursor and diphenyl ether as a solvent.

According to one embodiment, the first inorganic nanoparticle precursor is an iron precursor, the second inorganic nanoparticle precursor is sulfur, and the organic material is octadecylamine.

According to a further embodiment, the method further includes (B) purifying the heated mixture solution and dispersing the purified mixture solution in a dispersion medium and (C) coating the dispersion on an absorber layer.

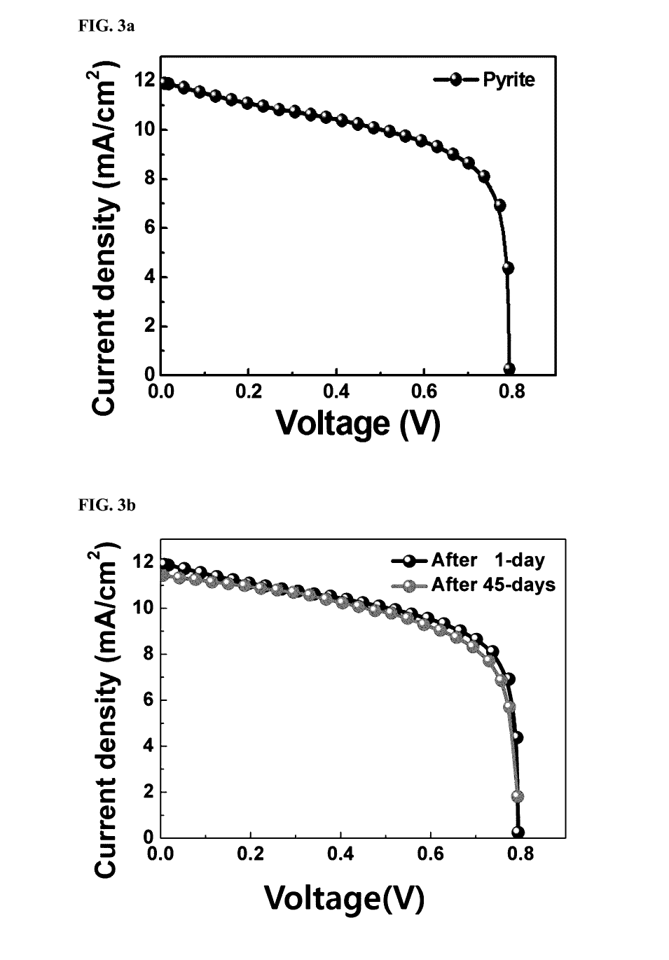

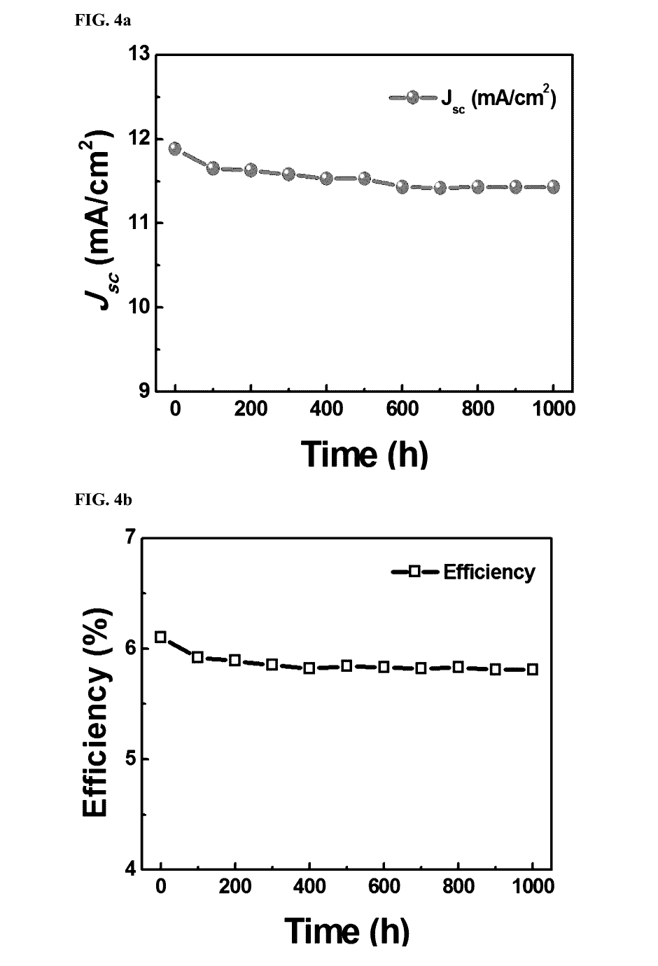

According to another embodiment, the mixture solution is heated to 200 to 250° C. and the dispersion medium is chloroform. In the Examples section that follows, a charge transport layer was formed by heating the mixture solution to the temperature range defined above, dispersing the mixture solution in chloroform, and coating the dispersion on an absorber layer, and a solar cell including the charge transport layer was fabricated. The solar cell was confirmed to maintain 96% of its initial photoelectric properties, photocurrent, and conversion efficiency, as shown in FIGS. 3b and 4b. A solar cells was fabricated in the same manner as described above, except that the heating temperature was outside the range defined above and the dispersion medium was other than chloroform. The photoelectric properties, photocurrent, and conversion efficiency of the solar cell remained as low as about 90% of their initial values.

A detailed description will be given concerning several aspects and embodiments of the present invention but the scope or disclosure of the present invention should not be construed as being limited thereto.

A first solar cell of the present invention may be an organic-inorganic hybrid perovskite solar cell including a first electrode, a metal oxide thin film formed on the first electrode, an absorber layer formed on the metal oxide thin film and including inorganic and organic semiconductors, a hole transport layer formed on the absorber layer, and a second electrode formed on the hole transport layer.

In the first solar cell, the metal oxide thin film may include at least one material selected from Ti oxides, Sn oxides, W oxides, Nb oxides, La oxides, V oxides, Al oxides, Mo oxides, Mg oxides, Zr oxides, Sr oxides, Yr oxides, Zn oxides, In oxides, Y oxides, Sc oxides, Sm oxides, Ga oxides, and composites thereof.

In the first solar cell, the hole transport layer may include Cu₂O, FeₓS_{y}, FeₐO_{b}, CuI, CuSCN or a d-metal chalcogenide or halide compound.

In the first solar cell, the light absorber is a compound having a perovskite structure.

A second solar cell of the present invention may be an organic-inorganic hybrid perovskite solar cell including a first electrode, a hole transport layer formed on the first electrode, an absorber layer formed on the hole transport layer and including inorganic and organic semiconductors, an electron transport layer formed on the absorber layer, and a second electrode formed on the electron transport layer.

In the second solar cell, the hole transport layer may include at least one material selected from poly(3,4-ethylenedioxythiophene)-poly(styrenesulfonate) (PEDOT:PSS), copper phthalocyanine (CuPC), graphene oxide, and composites thereof.

In the second solar cell, the electron transport layer may include at least one metal oxide selected from Ti oxides, Sn oxides, W oxides, Nb oxides, La oxides, V oxides, Al oxides, Mo oxides, Mg oxides, Zr oxides, Sr oxides, Yr oxides, Zn oxides, In oxides, Y oxides, Sc oxides, Sm oxides, and Ga oxides.

In the second solar cell, the light absorber is a compound having a perovskite structure.

There is no limitation on the material for the transparent conductive substrate. According to one embodiment of the present invention, the transparent conductive substrate may be, for example, a transparent glass, plastic or metal mesh substrate containing a material selected from the group consisting of tin oxides, such as indium tin oxide (ITO) and fluorine tin oxide (FTO), zinc oxides, and combinations thereof. Any suitable transparent conductive material may be used without particular limitation as a material for the transparent conductive substrate.

There is no limitation on the material for the plastic substrate. According to one embodiment of the present invention, the plastic substrate may include a polymer selected from the group consisting of poly(ethylene terephthalate) (PET), poly(ethylene naphthalate) (PEN), polycarbonate (PC), polypropylene (PP), polyimide (PI), triacetyl cellulose (TAC), and combinations thereof.

There is no limitation on the material for the hydrophobic inorganic charge transport layer. According to one embodiment of the present invention, the hydrophobic inorganic charge transport layer may include, as a hole transport material, a monolayer of nanoparticles, a combination of nanoparticles and a monomolecular compound or a blend of nanoparticles and a polymer. Examples of such charge transport materials based on inorganic nanoparticles include, but are not limited to, nanoparticles, including inorganic quantum dots of Group 14 element halides, and nanoparticles of inorganic compounds containing transition metals, such as CuSCN and CuI.

In the polymer blend, the polymer is not limited and may be, for example, polyaniline, poly(3,4-ethylenedioxythiophene)-poly(styrenesulfonate) (PEDOT:PSS), poly(triarylamine) (PTAA) or poly(4-butylphenyl-diphenyl-amine). The inorganic hole transport layer may further include a p-type dopant as a doping material. Examples of suitable p-type dopants include, but are not limited to, dopants from Group III-V elements, such as Cd, Zn, Mn, and Be. For example, the hole transport layer may be formed using FeS₂ nanoparticles and a metal ligand capable of Mn doping or a dopant but is not limited to these materials.

In this regard, a charge transport layer disposed on an absorber layer in an existing organic-inorganic hybrid perovskite solar cell uses charge carriers based on an expensive organic material. The charge carriers are prone to oxidation in air or the perovskite light absorber is liable to degrade with increasing external temperature or humidity, disadvantageously shortening the life of the solar cell.

In contrast, the organic-inorganic hybrid perovskite solar cell of the present invention does not use organic material-based charge carriers on the light absorber, unlike the existing solar cell, but includes the inorganic charge transport layer that plays the same role as the charge carriers. As a result, the solar cell of the present invention is free from the disadvantages encountered in the existing solar cell, has good long-term stability, and is fabricated in an economical manner. In addition, the hydrophobic inorganic nanoparticles included in the charge transport layer of the organic-inorganic hybrid perovskite solar cell according to the present invention ensure long-term stability of the light absorber susceptible to moisture.

According to one embodiment of the present invention, an organic material having a long alkyl chain as a stabilizer is introduced on the surface of the nanoparticles to make the charge transport layer hydrophobic. For example, a polymer, such as polyvinylpyrrolidone or poly(allylamine hydrochloride), or a copolymer, such as a poly(maleic anhydride-all-1-octadecene)-PEG block copolymer, amphiphilic PEG-phospholipid, polystyrene-polyacrylic acid block copolymer (PS-PAA), tetradecyl phosphonate or polyethylene glycol-2-tetradecyl ether, may be used as a ligand of the nanoparticles. The charge transport layer may further include an organic material, such as oleylamine, octadecylamine, dibenzyl amine or oleic acid, to modify the surface of the nanoparticles. Both the polymer and the monomolecular compound may be included in the charge transport layer. In this case, the combination of the polymer and monomolecular compound with the nanoparticles makes the charge transport layer more hydrophobic.

The use of the nanoparticles or the polymer blend with the nanoparticles for the formation of the charge transport layer can provide a solution to the problems encountered in the use of monomolecular or bulk materials, which limits the fabrication of flexible or stretchable solar cells.

The present invention will be explained in more detail with reference to the following examples. However, these examples are not to be construed as limiting or restricting the scope and disclosure of the invention. It is to be understood that based on the teachings of the present invention including the following examples, those skilled in the art can readily practice other embodiments of the present invention whose experimental results are not explicitly presented. It will also be understood that such modifications and variations are intended to come within the scope of the appended claims.

### EXAMPLES

### Preparative Example 1

### Preparation of Solution for Organic-Inorganic Hybrid Perovskite Absorbing Layer

Methylammonium iodide (CH₃NH₃I) and lead diiodide (PbI₂) in a molar ratio of 1:1 were dissolved in γ-butyrolactone. The solution was stirred at 60° C. for 12 h to prepare a solution of 40 wt % methylammonium lead triiodide (CH₃NH₃PbI₃).

### Example 1-1

### Preparation of Solution of Hydrophobic Inorganic Nanoparticles

0.15 mol of FeCl₂.4H₂O (Aldrich) was dispersed in 0.15 mol of octadecylamine (Aldrich). Residual moisture was removed at 100° C. for 1 h to prepare a first precursor solution. Sulfur was dispersed in diphenyl ether (Aldrich) in such an amount that the sulfur concentration was 15 mg/mL. Residual moisture was removed at 100° C. for 1 h to prepare a second precursor solution. The first precursor solution was sufficiently mixed with the second precursor solution in a 250 mL 3-neck flask. Thereafter, the mixture was thermally decomposed at 220° C. for a controlled time to synthesize nanoparticles. The nanoparticles were purified with a solution of ethyl alcohol and chloroform (9:1, v/v) and dispersed in chloroform.

### Example 1-2

### Fabrication of Organic-Inorganic Hybrid Perovskite Solar Cell

A glass substrate coated with F-doped SnO₂ (FTO) (8 ohms/cm², Pilkington) was cut to a size of 25×25 mm (hereinafter referred to as an FTO substrate or first electrode). A 0.1 M Ti (IV) bis(ethyl acetoacetato)diisopropoxide (Aldrich)/1-butanol (Aldrich) solution was spin coated on the first electrode, followed by heat treatment at about 500° C. for about 15 min to form an about 100 nm thick dense anatase TiO₂ thin film as an n-type semiconductor layer.

A solution of 10 wt % of ethyl cellulose and terpinol were added to and mixed with a TiO₂ powder (average particle size=20 nm) to prepare a paste solution in which ethyl alcohol and the TiO₂ powder were present in a ratio of 8:2. The ethyl cellulose solution and the terpinol were used in amounts of 5 mL and 5 g per gram of the TiO₂, respectively.

The paste solution was spin coated on the TiO₂ thin film formed on the FTO substrate, followed by heat treatment at 500° C. for 60 min to form a porous support layer. The light absorber (CH₃NH₃PbI₃) solution prepared in Preparative Example 1 was spin coated on the support layer at 2000 rpm for 60 sec and at 3000 rpm for 60 sec and dried on a hot plate at 100° C. for 10 min to form an organic-inorganic hybrid perovskite absorber (CH₃NH₃PbI₃) layer.

The dispersion of iron pyrite (FeS₂) nanoparticles in chloroform (15 mg/l mL) prepared in Example 1-1 was spin coated on the substrate coated with the perovskite light absorber at 1500 rpm for 30 sec to form a hole transport layer. Thereafter, Au was deposited on the hole transport layer using a thermal evaporator under a high vacuum (≦5×10′ torr) to form an about 100 nm thick Au electrode (second electrode), completing the fabrication of a solar cell.

The current-voltage characteristics of the solar cell were analyzed using a solar simulator under AM 1.5 G illumination (100 mW/cm²).

### Test Example 1

### Evaluation of Photoelectric Properties of the Perovskite Solar Cell Employing the Iron Pyrite-Based Hole Carriers

The current-voltage properties of the solar cell employing the iron pyrite-based hole carriers fabricated in Example 1 were measured under AM 1.5 G illumination (100 mW/cm²).

TABLE 1

| Properties | J_{sc} (mA/cm²) | V_{oc} (V) | FF | η (%) |
|---|---|---|---|---|
| Iron pyrite | 11.88 | 0.79 | 0.65 | 6.10 |
| Copper iodide | 13.94 | 0.65 | 0.60 | 5.44 |

Table 1 and FIG. 3a show high photoelectric efficiency of the solar cell employing the iron pyrite-based hole carriers. As can be seen from FIG. 3b, the device stably maintained its initial photoelectric properties even after 45 days, revealing that the hydrophobic hole carriers improved the stability of the device.

### Test Example 2

### Evaluation of Photoelectric Properties of Perovskite Solar Cell Employing Copper Iodide-Based Hole Carriers

A perovskite solar cell was fabricated in the same manner as in Example 1, except that copper iodide-based hole carriers were used instead of iron pyrite-based carriers. The photoelectric properties of the perovskite solar cell were evaluated in the same manner as in Test Example 1.

As shown in Table 1, the solar cell employing the copper iodide-based hole carriers showed photoelectric properties similar to those of the device employing the iron pyrite-based hole carriers, demonstrating the ability of the copper iodide-based hole carriers to transport holes.

### Example 2-1

### Preparation of Solution of Hydrophobic Inorganic Nanoparticles

0.5 g of CuCl was dispersed in a mixture solution of 10 mL of oleic acid, 10 mL of oleylamine, and 20 mL of octadecene. The dispersion was heated at 120° C. for 1 h. After the dispersion was cooled to 25° C., 0.7 mL of hydroiodic acid was added thereto. The mixture solution was allowed to stand under an Ar gas atmosphere for 20 min, heated at 80° C. 3 h, and cooled to 25° C. Isopropanol was added to the reaction solution, purified by centrifugation, and dispersed in hexane.

### Example 2-2

### Fabrication of Organic-Inorganic Hybrid Perovskite Solar Cell

A glass substrate coated with F-doped SnO₂ (FTO) (8 ohms/cm², Pilkington) was cut to a size of 25×25 mm (hereinafter referred to as an FTO substrate or first electrode). A 0.1 M Ti (IV) bis(ethyl acetoacetato)diisopropoxide (Aldrich)/1-butanol (Aldrich) solution was spin coated on the first electrode, followed by heat treatment at about 500° C. for about 15 min to form an about 100 nm thick dense anatase TiO₂ thin film as an n-type semiconductor layer.

A solution of 10 wt % of ethyl cellulose and terpinol were added to and mixed with a TiO₂ powder (average particle size=20 nm) to prepare a paste solution in which ethyl alcohol and the TiO₂ powder were present in a ratio of 8:2. The ethyl cellulose solution and the terpinol were used in amounts of 5 mL and 5 g per gram of the TiO₂, respectively.

The paste solution was spin coated on the TiO₂ thin film formed on the FTO substrate, followed by heat treatment at 500° C. for 60 min to form a porous support layer. The light absorber (CH₃NH₃PbI₃) solution prepared in Preparative Example 1 was spin coated on the support layer at 2000 rpm for 60 sec and at 3000 rpm for 60 sec and dried on a hot plate at 100° C. for 10 min to form an organic-inorganic hybrid perovskite absorber (CH₃NH₃PbI₃) layer.

The dispersion of copper iodide (CuI) nanoparticles in hexane (30 mg/l mL) prepared in Example 2-1 was spin coated on the substrate coated with the perovskite light absorber at 2000 rpm for 30 sec to form a hole transport layer. Thereafter, Au was deposited on the hole transport layer using a thermal evaporator under a high vacuum (≦5×10′ torr) to form an about 100 nm thick Au electrode (second electrode), completing the fabrication of a solar cell.

The current-voltage characteristics of the solar cell were analyzed using a solar simulator under AM 1.5 G illumination (100 mW/cm²).

The performance characteristics of the solar cell were compared with those of the solar cell fabricated in Example 1-2. As a result, the solar cell fabricated in Example 2-2 showed slightly low Voc and FF values but had a high Jsc compared to the solar cell fabricated in Example 1-2, demonstrating the ability of the copper iodide-based hole carriers to transport holes.

What is claimed is:

1. A charge transport layer for a solar cell comprising core-shell nanoparticles consisting of (a) an inorganic nanoparticle core and (b) an organic material shell surrounding the surface of the inorganic nanoparticle core

2. The charge transport layer according to claim 1, wherein the inorganic nanoparticles are nanoparticles of a material selected from FeₓS_{y} (x is an integer from 1 to 7 and y is an integer from 1 to 8), FeₐO_{b} (a is an integer from 1 to 4 and b is an integer from 1 to 4), CuI, CuF, CuCl, CuBr, Cu₂O, CuSCN, and mixtures thereof.

3. The charge transport layer according to claim 1, wherein the organic material is selected from octadecylamine, oleylamine, dibenzylamine, oleic acid, polyvinylpyrrolidone, poly(allylamine hydrochloride), polyethyleneimine, poly(maleic anhydride-alt-1-octadecene)-polyethylene glycol block copolymers, amphiphilic polyethylene glycol-phospholipid, polystyrene-polyacrylic acid block copolymers, tetradecyl phosphonate, polyethylene glycol-2-tetradecyl ether, and mixtures thereof.

4. The charge transport layer according to claim 1, wherein the inorganic nanoparticles are FeS₂ nanoparticles and the organic material is octadecylamine.

5. The charge transport layer according to claim 1, wherein the charge transport layer is a hole transport layer.

6. A solar cell comprising the charge transport layer according to claim 1.

7. The solar cell according to claim 6, further comprising an organic-inorganic hybrid perovskite absorber layer.

8. The solar cell according to claim 7, wherein the organic-inorganic hybrid perovskite is CH₃NH₃PbI₃.

9. The solar cell according to claim 8, wherein the solar cell comprises (a) a transparent conductive substrate, (b) a metal oxide thin film formed on the transparent conductive substrate, (c) the absorber layer formed on the metal oxide thin film, (d) the charge transport layer formed on the absorber layer, and (e) an electrode formed on the charge transport layer.

10. The solar cell according to claim 8, wherein the solar cell comprises (a) a transparent conductive substrate, (b) a hole transport layer formed on the transparent conductive substrate, (c) the absorber layer formed on the hole transport layer, (d) the charge transport layer formed on the absorber layer, and (e) an electrode formed on the charge transport layer.
